(19) United States
(12) Patent Application Publication
(10) Pub. No.: US 2024/0047229 A1
(43) Pub. Date: Feb. 8, 2024

(54) ORGANIC PACKAGE CORE FOR A SUBSTRATE WITH HIGH DENSITY PLATED HOLES

(71) Applicant: ADVANCED MICRO DEVICES, INC., SANTA CLARA, CA (US)

(72) Inventors: SRI RANGA SAI BOYAPATI, AUSTIN, TX (US); RAJA SWAMINATHAN, AUSTIN, TX (US); DEEPAK VASANT KULKARNI, AUSTIN, TX (US)

(21) Appl. No.: 17/879,110

(22) Filed: Aug. 2, 2022

(51) Int. Cl. H01L 21/48; H01L 23/498

(52) U.S. Cl. CPC H01L 21/486; H01L 23/49822; H01L 21/4857; H01L 23/49838; H01L 23/49894; H01L 21/6835

(57) ABSTRACT

A method for forming a core for a substrate that removes portions of a resist layer based on a pattern specifying widths of removed portions of the resist layer. The method forms a set of pillars by plating the remaining portions of the resist layer with a conductive material, so each pillar of the set has a perimeter plated with the conductive material. Additionally, each pillar of the set of pillars is encapsulated with a dielectric material. In some implementations, the dielectric material is an organic material.

### BACKGROUND

Conventional techniques for creating holes, such as plated through holes, in cores for package substrates drill the holes through the core. For example, mechanical drilling or laser drilling is conventionally used to create holes in a core. These drilling techniques place a limit on minimum spacing between holes in the core. For example, spacing between holes in the core is limited by accuracy with which mechanical drill bits or lasers can be placed on the core.

### BRIEF DESCRIPTION OF THE DRAWINGS

FIG. 1 is part of a process flow for manufacturing a semiconductor core including high-density plated holes according to some implementations.

FIG. 2 is part of a process flow for manufacturing a semiconductor core including high-density plated holes according to some implementations.

FIG. 3 is part of a process flow for manufacturing a semiconductor core including high-density plated holes according to some implementations.

FIG. 4 is part of a process flow for manufacturing a semiconductor core including high-density plated holes according to some implementations.

FIG. 5 is part of a process flow for manufacturing a semiconductor core including high-density plated holes according to some implementations.

FIG. 6 is part of a process flow for manufacturing a semiconductor core including high-density plated holes according to some implementations.

FIG. 7 is part of a process flow for manufacturing a semiconductor core including high-density plated holes according to some implementations.

FIG. 8 is part of a process flow for manufacturing a semiconductor core including high-density plated holes according to some implementations.

FIG. 9 is part of a process flow for manufacturing a semiconductor core including high-density plated holes according to some implementations.

FIG. 10 is part of a process flow for manufacturing a semiconductor core including high-density plated holes according to some implementations.

FIG. 11 is part of a process flow for manufacturing a semiconductor core including high-density plated holes according to some implementations.

FIG. 12 is part of a process flow for manufacturing a semiconductor core including high-density plated holes according to some implementations.

FIG. 13 is part of a process flow for manufacturing a semiconductor core including high-density plated holes according to some implementations.

FIG. 14 is part of a process flow for manufacturing a semiconductor core including high-density plated holes according to some implementations.

FIG. 15 is part of a process flow for manufacturing a semiconductor core including high-density plated holes according to some implementations.

FIG. 16 is part of a process flow for manufacturing a semiconductor core including high-density plated holes according to some implementations.

FIG. 17 is part of a process flow for manufacturing a semiconductor core including high-density plated holes according to some implementations.

FIG. 18 is part of a process flow for manufacturing a semiconductor core including high-density plated holes according to some implementations.

FIG. 19 is part of a process flow for manufacturing a semiconductor core including high-density plated holes according to some implementations.

FIG. 20 is part of a process flow for manufacturing a semiconductor core including high-density plated holes according to some implementations.

FIG. 21 is a cross-sectional diagram of an example integrated circuit device 200 including a substrate having conductive pillars encapsulated by a dielectric material according to some implementations.

FIG. 22 is an example computing device according to some implementations.

FIG. 23 is a flow chart illustrating an example method for manufacturing an integrated circuit device assembly including a substrate having conductive pillars encapsulated by a dielectric material according to some implementations.

FIG. 24 is a flow chart illustrating an example method for manufacturing an integrated circuit device assembly including a substrate having conductive pillars encapsulated by a dielectric material according to some implementations.

FIG. 25 is a flow chart illustrating an example method for manufacturing an integrated circuit device assembly including a substrate having conductive pillars encapsulated by a dielectric material according to some implementations.

### DETAILED DESCRIPTION

Holes in a core for a semiconductor substrate, such as plated through holes, establish electrical connections between components. Such holes allow components on different layers of a semiconductor to be electrically connected to each other. For example, a hole in a core are plated with a conductive material, such as copper, to make an inner area of the hole conductive. Such plating improves mechanical stability while reducing resistance to improve current flow between components.

Creating holes in a core using mechanical drilling or through use of a laser limits a minimum spacing between the holes. However, reducing minimum spacing between holes in a core allows increasing power consumption by semiconductors to be addressed. For example, reducing minimum spacing between holes in a core allows discrete power regulation components, such as inductors or capacitors, to be embedded in the package substrate core for a semiconductor. Mechanical or laser drilling of holes in a core limits the ability to include such power regulation components in a core based on the spacing between holes for effective use of mechanical or laser drilling.

To that end, the present specification sets forth various implementations of a method for forming a core for a substrate that removes portions of a resist layer based on a pattern specifying widths of removed portions of the resist layer. The method forms a set of pillars by plating the remaining portions of the resist layer with a conductive material, so each pillar of the set has a perimeter plated with the conductive material. Additionally, each pillar of the set of pillars is encapsulated with a dielectric material. In some implementations, the dielectric material is an organic material. The dielectric material is a low loss resin or glass filler in some implementations.

In some implementations, the dielectric material encapsulating each pillar of the set of pillars is applied using compression molding. In other implementations, the dielectric material encapsulating each pillar of the set of pillars is applied using vacuum lamination. In various implementations, the dielectric material encapsulating each pillar of the set of pillars is applied using liquid coating.

In some implementations, the method further removes portions of the dielectric material that are higher than a height of the pillars of the set. Portions of the dielectric material higher than the height of the pillars of the set are ground to be removed in some implementations.

In some implementations, the method also includes coupling a first conductive pad to a first end of the pillar, where the first conductive pad is proximate to a first surface of the dielectric material. The method further couples a second conductive pad to a second end of the pillar, where the second end of the pillar is opposite the first end of the pillar and the second conductive pad is proximate to a second surface of the dielectric material that is opposite the first surface of the dielectric material. In some implementations, the first conductive pad is coupled to the first end of the pillar by applying an additional layer of the conductive material to a surface of set of pillars nearest the first surface of the dielectric material and by removing portions of the additional layer of the conductive material other than the first conductive pad.

In some implementations, the method further forms an additional pillar by lithographically removing portions of an additional resist layer applied to the additional layer of the conductive material and plating an additional perimeter of a remaining portion of the additional resist layer with the conductive material, where a perimeter the additional pillar comprising the conductive material and an end of the additional pillar contacts the first conductive pad coupled to the first end of the pillar in some implementations. The method also encapsulates the additional pillar with additional dielectric material where a surface of the additional dielectric material is proximate to the first surface of the dielectric material in various implementations. In various implementations, the method further couples a third conductive pad to an additional end of the additional pillar, with the additional end of the additional pillar opposite the end of the additional pillar and the third conductive pad proximate to an additional surface of the additional dielectric material that is opposite the surface of the additional dielectric material

In some implementations adjacent pillars of the set are separated by a distance between centers of adjacent pillars that does not exceed 400 microns. In other implementations, adjacent pillars of the set are separated by a distance between centers of adjacent pillars that does not exceed 200 microns.

The present specification also describes a substrate core including a pillar having a perimeter plated with a conductive material, with the pillar formed by lithographically removing portions of a resist layer and plating a perimeter of a remaining portion of the resist layer with the conductive material with the conductive material. Dielectric material encapsulates the pillar. The substrate core also includes an additional pillar, where a perimeter of the additional pillar comprising the conductive material and an end of the additional pillar contacting a first conductive pad coupled to a first end of the pillar and the additional pillar is formed by lithographically removing portions of an additional resist layer and plating an additional perimeter of a remaining portion of the additional resist layer with the conductive material. Additional dielectric material encapsulates the additional dielectric material, with a surface of the additional dielectric material proximate to a first surface of the dielectric material that is proximate to the first end of the pillar. In some implementations, the dielectric material is an organic material. The additional dielectric material is an organic material in some implementations.

In some implementations, the substrate core further includes a second conductive pad coupled to a second end of the pillar, with the second end of the pillar opposite the first end of the pillar and the second conductive pad proximate to a second surface of the dielectric material that is opposite the first surface of the dielectric material. In some implementations, the pillar is included in a set of pillars, where adjacent pillars of the set are separated by a distance between centers of adjacent pillars that does not exceed 400 microns. In other implementations, the pillar is included in a set of pillars, where adjacent pillars of the set are separated by a distance between centers of adjacent pillars that does not exceed 200 microns.

The following disclosure provides many different implementations, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows include implementations in which the first and second features are formed in direct contact, and also include implementations in which additional features formed between the first and second features, such that the first and second features are in direct contact. Further, spatially relative terms, such as “beneath,” “below,” “lower,” “above,” “upper,” “back,” “front,” “top,” “bottom,” and the like, are used herein for ease of description to describe one element or feature's relationship to another element(s) or feature(s) as illustrated in the figures. Similarly, terms such as “front surface” and “back surface” or “top surface” and “back surface” are used herein to more easily identify various components, and identify that those components are, for example, on opposing sides of another component. The spatially relative terms are intended to encompass different orientations of the device in use or operation in addition to the orientation depicted in the figures.

FIGS. 1-20 show steps in an example manufacturing process for a core for a substrate having a high density of holes, such as plated through holes. Beginning with FIG. 1, a resist layer 105 is applied to a layer 100 of conductive material. In some implementations, the conductive material is copper, while in other implementations other conductive materials capable of being electroplated are used. The resist layer 105 is a dry film resist laminate layer in some implementations. The resist layer 105 has a thickness ranging between 150 microns and 200 microns in some implementations, while the resist layer 105 has different thicknesses in other implementations.

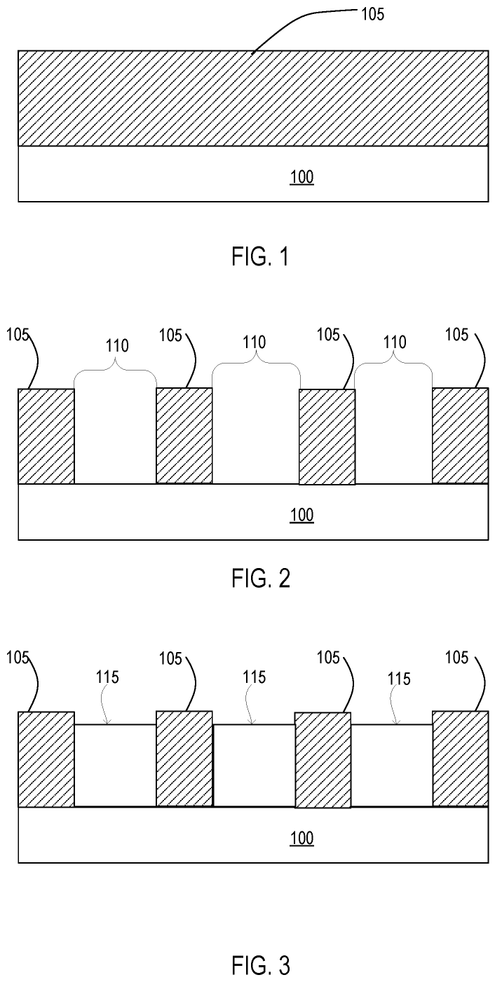

Referring to FIG. 2, portions 110 of the resist layer 105 are removed, creating a pattern from the remaining portions of the resist layer 105 and the removed portions 110 of the resist layer 105. For example, photolithography is used to remove the portions 110 of the resist layer 105 based on a pattern specifying a width of the removed portions 110 of the resist layer 105; however, in other implementations different techniques or combinations of techniques are used to remove the portions 110 of the resist layer 105. In some examples, the pattern specifies a width less than 400 micron or specifies a width less than 200 microns, which corresponds to the width of a removed portion 110 of the resist layer; however, in other implementations, the pattern specifies one or more different widths for the removed portions 110 of the resist layer 105. In some implementations, the pattern specifies a uniform width for each removed portion 110 of the resist layer 105. In the example of FIG. 2, removal of the portions 110 of the resist layer 105 results in columns of the resist layer 105 separated by the removed portions 110 of the resist layer 105. In some implementations, an etch stop is applied with the resist layer 105.

In FIG. 3, conductive material is applied to the removed portions 110 of the resist layer along a surface of the resist layer 105 opposite the layer 100 of conductive material. In various implementations, the conductive material applied to the removed portions 110 of the resist layer 105 is the same as the conductive material forming the layer 100 of conductive material. For example, the conductive material comprising the layer 100 of conductive material is copper, so copper is applied to the removed portions 110 of the resist layer. The conductive material is applied via electroplating in some implementations, while in other implementations other methods are used to apply the conductive material. The resist layer 105 is an inhibitor to conductive material in various implementations, so the conductive material occupies portions 110 where the resist layer 105 was removed in FIG. 2. Hence, application of the conductive material forms pillars 115 of the conductive material in the portions 110 where the resist layer 105 was removed, as described in FIG. 2. In some implementations, the pillars 115 are hollow with a perimeter formed by the conductive material and having a shape defined by a shape of the removed portions 110 of the resist layer 105. The pillars 115 have a height that is determined by a height of the remaining portions of the resist layer 105 in various implementations. For example, a height of a pillar 115 is a height of a remaining portion 110 of the resist layer 105 less a threshold amount (e.g., 5 microns).

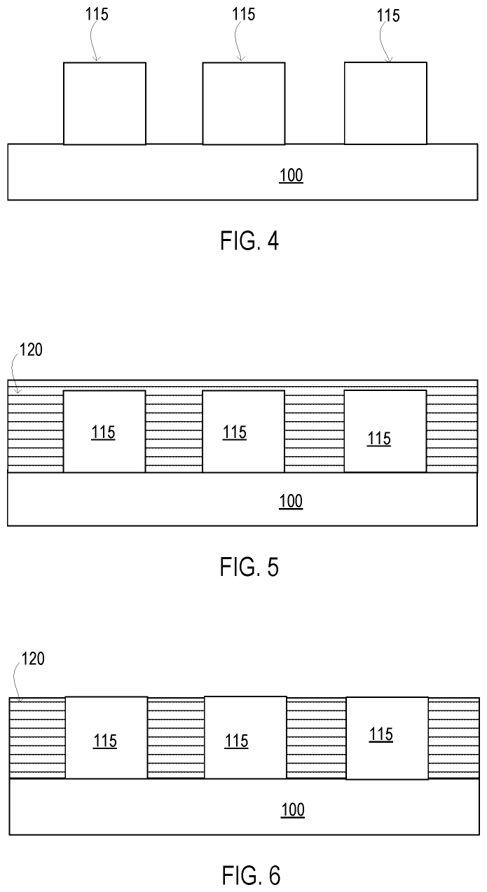

In FIG. 4, the remaining portions of the resist layer 105 are removed. For example, the resist layer 105 is removed using photolithography, while in other examples one or more other methods are used to remove the remaining portions of the resist layer 105. As shown in FIG. 4, removing the remaining portions of the resist layer 105 results in the pillars 115 of the conductive material layered on the layer 100 of the conductive material. In various implementations, as described above, the pillars 115 are hollow, with the conductive material forming a perimeter around a pillar 115 and extending in a direction perpendicular to the layer 100 of the conductive material.

The pillars 115 are encapsulated in a dielectric material 120 in FIG. 5. In some implementations, the dielectric material 120 surrounds the pillars 115 by occupying spaces between the pillars 115; hence, encapsulating a pillar 115 with the dielectric material 120 causes the dielectric material to fill regions where the remaining portions of the resist layer were removed in FIG. 4. Thus, the pillars 115 are encapsulated in the dielectric material 120 after the pillars 115 have been formed. In some implementations, a conversion coating is applied to the pillars 115 before the pillars 115 are encapsulated in the dielectric material 120 to improve adhesion of the dielectric material 120 to a surface of the pillars 115. For example, black oxide is applied to the pillars 115 with the dielectric material 120 applied after application of the black oxide to improve adhesion of the dielectric material 120 to the pillars 115. In various implementations the dielectric material 120 is an organic material. For example, the dielectric material 120 includes resin and glass filler, such as low loss resin or glass filler. Further, the dielectric material 120 is a flame redardant-4 (“FR-4”) material in various implementations. The dielectric material 120 is applied using compression molding in some implementations. In other implementations the dielectric material 120 is applied using vacuum lamination, while in further implementations the dielectric material 120 is applied via liquid coating. However, different methods or combinations of methods are used to encapsulate the pillars 115 with the dielectric material 120 in various implementations.

Dielectric material 120 higher than a height of the pillars 115 is removed in FIG. 6 so the dielectric material 120 is within a threshold distance of a top surface of the pillars 115 that is parallel to the layer 100 of the conductive material. In some implementations, dielectric material 120 is removed so the dielectric material is flush (e.g., coplanar) with the top surface of the pillars 115 that is parallel to the layer 100 of the conductive material. A grinding process is used to remove the dielectric material 120 that is higher than the height of the pillars 115 in some implementations, while one or more other methods for removing dielectric material 120 are used in various other implementations.

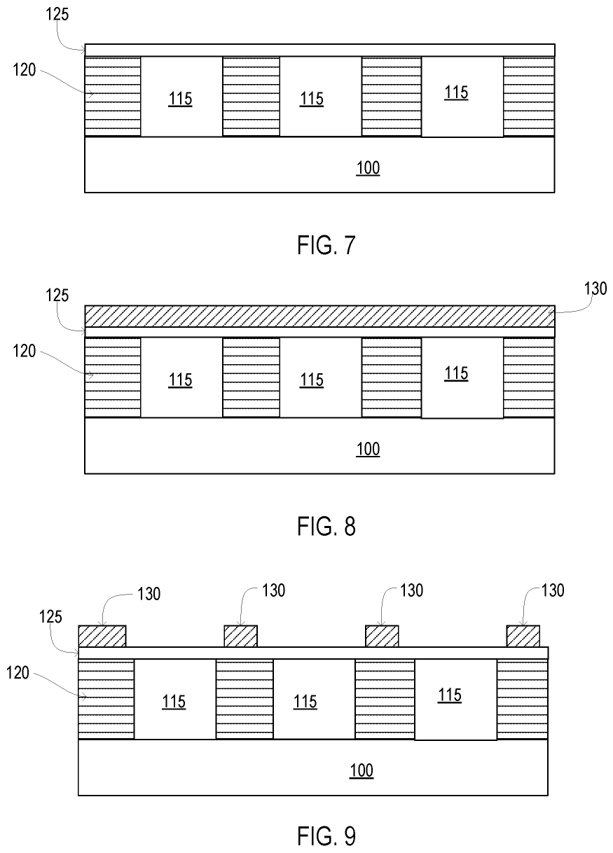

An additional layer 125 of the conductive material is applied to the top surface of the pillars 115, as shown in FIG. 7. In some implementations, after removing the portions of the dielectric material 120 in FIG. 6, a desmearing process is performed to remove remaining portions of the dielectric material 120 on the top surfaces of the pillars 115. In some examples, a solution is applied to the top surface of the pillars 115 to remove excess dielectric material 120 or a plasma treatment is performed to the top surface of the pillars 115 to remove excess dielectric material 120. In various implementations, the desmearing process also roughens the top surface of the pillars 115 to promote adhesion of the additional layer 125 of the conductive material to the top surfaces of various pillars 115. The additional layer 125 of the conductive material is applied through an electroless plating process (e.g., an electroless copper plating) in various implementations.

An additional resist layer 130 is applied to the additional layer 125 of the conductive material in FIG. 8. The additional resist layer 130 and the resist layer 105 are a common material in various implementations. The additional resist layer 130 is thinner than the resist layer 105 applied in FIG. 1 in various implementations.

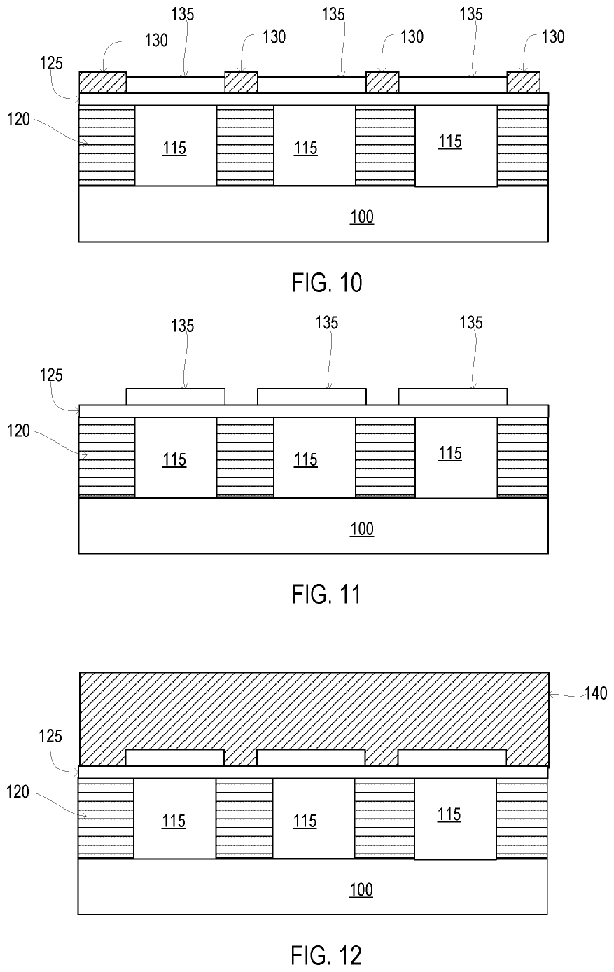

As shown in FIG. 9, portions of the additional resist layer 130 are removed from portions of the additional layer 125 of the conductive material, while portions of the additional resist layer 130 remain on the additional layer 125 of the conductive material. This creates a pattern from the portions of the additional resist layer 130 that are removed and the portions of the additional resist layer 130 that remain. For example, photolithography is used to remove one or more portions of the additional resist layer 130 based on a pattern based on a pattern specifying one or more widths of portions of the additional resist layer 130 to remove or portions of the additional resist layer 130 to remain on the additional layer 125 of the conductive material; however, in other implementations different techniques or combinations of techniques are used to remove portions of the additional resist layer 130.

Conductive material 135 is applied to the portions of the additional layer 125 of the conductive material exposed after removal of the additional resist layer 130, as shown in FIG. 10. In some implementations, the conductive material 135 is applied via one or more electroplating processes, while in other implementations the conductive material 135 is applied using other suitable methods. After application of the conductive material 135 to the portions of the additional layer 125 of the conductive material exposed after removal of the additional resist layer 130, the remaining portions of the additional resist layer 130 are removed, as shown in FIG. 11. For example, the remaining portions of the additional resist layer 130 are removed using photolithography, while in other examples one or more other methods are used to remove the remaining portions of the additional resist layer 130. As shown in FIG. 11, removing the remaining portions of the additional resist layer 130 results in the conductive material 135 forming conductive pads covering a top surface of the pillars 115, where the top surface of the pillars is parallel to the layer 100 of conductive material. In some implementations, a conductive pad covering a top surface of the pillar 115 seals the top of the pillar 115.

To increase a thickness of the core, in some implementations, a third resist layer 140 of is applied to the conductive material 135 and to a top surface of the dielectric material 120 that is in a plane parallel to the layer 100 of the conductive material, as shown in FIG. 12. The third resist layer 140 is a dry film resist laminate layer in some implementations, while other implementations use other types of material for the third resist layer 140. The third resist layer 140 has a thickness ranging between 150 microns and 200 microns in some implementations, while the third resist layer 140 has different thicknesses in other implementations. In some implementations, the third resist layer 140 has the same thickness as the resist layer 105 applied to the layer 100 of the conductive material.

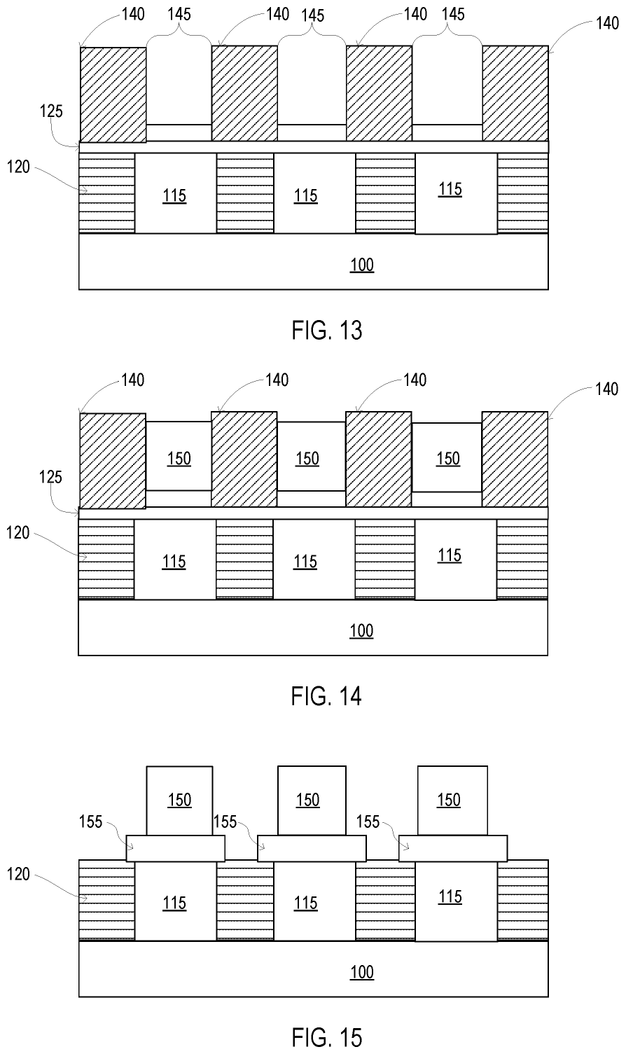

Referring to FIG. 13, portions 145 of the third resist layer 140 are removed, creating a pattern from the remaining portions of the third resist layer 140 and the removed portions 145 of the third resist layer 140. For example, photolithography is used to remove the portions 110 of the third resist layer 140 based on a pattern specifying a width of the removed portions 145 of the third resist layer 140; however, in other implementations different techniques or combinations of techniques are used to remove the portions 145 of the third resist layer 140. In an example, the pattern specifies a width of 200 microns, which corresponds to the width of a removed portion 145 of the third resist layer 140; however, in other implementations, the pattern specifies one or more different widths for the removed portions 145 of the third resist layer 140. In some implementations, the pattern specifies a uniform width for each removed portion 145 of the third resist layer 140. In the example of FIG. 13, removal of the portions 145 of the third resist layer 140 results in columns of the third resist layer 140 separated by the removed portions 145 of the third resist layer 140. In some implementations, the pattern used to remove the portions 110 of the resist layer 105 further described above in conjunction with FIG. 2 is used to remove the portions 145 of the third resist layer 140, allowing removal of the portions 145 of the third resist layer 140 to replicate the pattern formed by removal of the portions 110 of the resist layer 105.

In FIG. 14, conductive material is applied to a surface of the third resist layer 140 opposite the conductive material 135 applied to the top surface of the pillars 115. In various implementations, the conductive material applied to the portions 145 where the third resist layer 140 was removed is the same as the conductive material forming the perimeter of the pillars 115. In other implementations, the conductive material applied to the portions 145 where the resist layer 140 was removed is the same as the conductive material 135 applied to the top surfaces of the pillars 115. For example, the conductive material comprising the layer 100 of conductive material is copper, comprising the pillars 115, applied to the top surface of the pillars, and applied to the portions 145 where the third resist layer 140 was removed is copper. The conductive material is applied via electroplating in some implementations, while in other implementations other methods are used to apply the conductive material. The third resist layer 140 is an inhibitor to conductive material in various implementations, so the conductive material occupies portions 145 where the third resist layer 140 was removed in FIG. 13. Hence, application of the conductive material forms additional pillars 150 of the conductive material in the portions 145 where the third resist layer 140 was removed, as described in FIG. 13. In some implementations, the additional pillars 150 are hollow with a perimeter formed by the conductive material and having a shape defined by a shape of the removed portions 145 of the third resist layer 140. The additional pillars 150 have a height that is determined by a height of the remaining portions of the resist layer 140 in various implementations. For example, a height of an additional pillar 150 is a height of a remaining portion of the resist layer 140 less a threshold amount (e.g., 5 microns).

The remaining portions of the third resist layer 140 are removed and the additional layer 125 of conductive material is removed in FIG. 15. Removing the additional layer 125 of conductive material and the remaining portions of the third resist layer 140 results in a conductive pad 155 coupling a pillar 115 to an additional pillar 150. For example, the conductive pad 155 couples a top surface of a pillar 115 to a bottom surface of an additional pillar 150. In some implementations where the pillar 115 and the additional pillar 150 are hollow, the pad 155 does not have an opening, providing a solid plane of conductive material to which the pillar 115 and the additional pillar 150 are coupled, as shown in in FIG. 15. In various implementations, such as shown in FIG. 15, a width of a conductive pad 155 is greater than a width of the pillar 115 and a width of the additional pillar 150 that are coupled to the conductive pad 155.

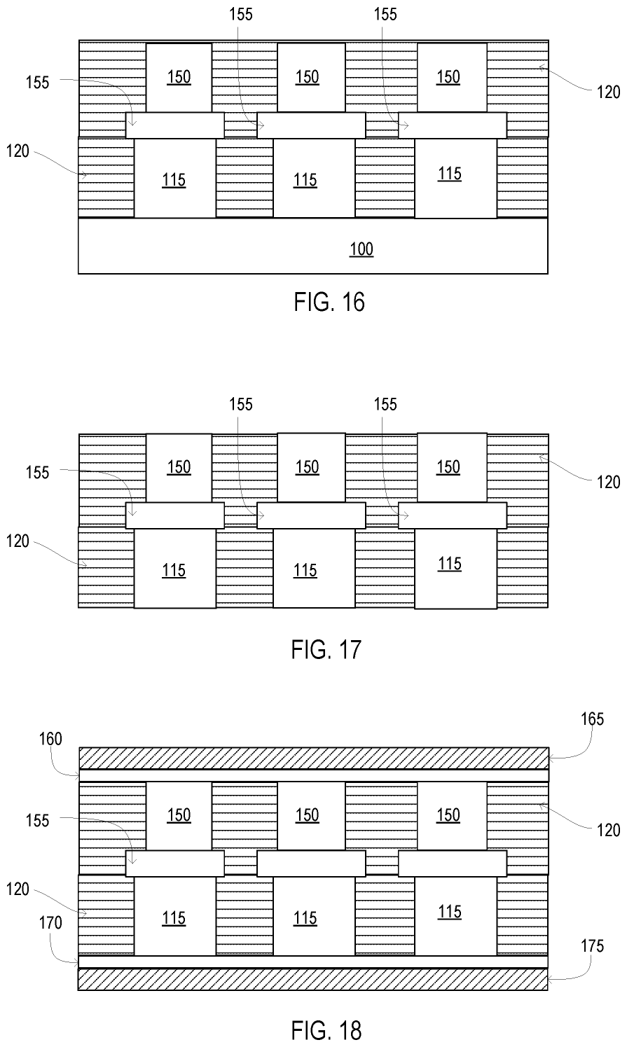

After removing the remaining portions of the third resist layer 140 and the additional layer 125 of conductive material, additional dielectric material 120 is applied to encapsulate the additional pillars 150 in the additional dielectric material 120 in FIG. 16. Thus, the additional dielectric material 120 encapsulates the additional pillars 150 after the additional pillars 150 have been formed. The dielectric material 120 surrounds the additional pillars 150 in some implementations. In various implementations, the dielectric material encapsulates the additional pillars 150 by occupying spaces between the additional pillars 150; hence, the dielectric material 120 fills regions where the portions of the additional resist layer 140 was removed after the additional pillars 150 were formed in FIG. 15. In some implementations, a conversion coating is applied to the additional pillars 150 before the additional pillars 150 are encapsulated in the dielectric material 120 to improve adhesion of the dielectric material 120 to one or more surfaces of the additional pillars 150. For example, black oxide is applied to the additional pillars 150 prior to application of the additional dielectric material 120 to improve adhesion of the dielectric material 120 to the additional pillars 150. In various implementations the dielectric material 120 is an organic material, such as a material comprising resin and glass filler or a flame redardant-4 (“FR-4”). The dielectric material 120 is applied using compression molding in some implementations. In other implementations the dielectric material 120 is applied using vacuum lamination, while in further implementations the dielectric material 120 is applied via liquid coating. However, different methods or combinations of methods are used to encapsulate the additional pillars 150 with the dielectric material 120 in various implementations.

Additional dielectric material 120 higher than a height of the additional pillars 150 is removed in FIG. 17, resulting in the dielectric material 120 being within a threshold distance of a top surface of the additional pillars 150 that is parallel to the conductive pad 155 coupling a pillar 115 to an additional pillar 150. In some implementations, removal of the dielectric material 120 higher than the top surface of the additional pillars 150 causes the additional dielectric material 120 around the additional pillars 150 to be flush (e.g., coplanar) with the top surface of the additional pillars 150 that is parallel to the conductive pads 155. A grinding process is used to remove the additional dielectric material 120 that is higher than the height of the additional pillars 150 in some implementations, while one or more other methods for removing dielectric material 120 are used in various other implementations.

Additionally, in FIG. 17, the layer 100 of conductive material is removed. In various implementations, one or more etching processes are used to remove the layer 100 of conductive material. In implementations where an etch stop was applied in conjunction with the layer 100 of conductive material, the etch stop is also removed.

In FIG. 18, a third layer 160 of the conductive material is applied to the top surface of the additional pillars 150 and to a surface of the additional dielectric material 120 proximate to the top surface of the additional pillars 150. In some implementations, after removing the portions of the additional dielectric material 120 in FIG. 17, a desmearing process is performed to remove remaining portions of the additional dielectric material 120 on the top surfaces of the additional pillars 150. In some examples, a solution is applied to the top surface of the pillars 150 to remove excess dielectric material 120 or a plasma treatment is performed to the top surface of the additional pillars 150 to remove excess additional dielectric material 120. In various implementations, the desmearing process also roughens the top surface of the additional pillars 150 to promote adhesion of the third layer 160 of the conductive material to the top surfaces of various additional pillars 150. The third layer 160 of the conductive material is applied through an electroless plating process (e.g., an electroless copper plating) in various implementations. In some implementations, the desmearing process is applied to bottom surfaces of the pillars 115 (e.g., surfaces of the pillars 115 previously proximate to the layer 100 of conductive material).

Further, a fourth resist layer 165 is applied to the third layer 160 of the conductive material in FIG. 18. The fourth resist layer 165 uses the same material as the resist layer 105, the additional resist layer 130, and the third resist layer 140 in various implementations. In other implementations, the fourth resist layer 165 is a common material as at least one of the resist layer 105, the additional resist layer 130, and the third resist layer 140; however, in further implementations, the fourth resist layer 165 is a different material than the resist layer 105, the additional resist layer 130, and the third resist layer 140. The fourth resist layer 165 is thinner than the third resist layer 140 in various implementations. For example, the fourth resist layer 165 has a common thickness as the additional resist layer 130.

Similarly, FIG. 18 shows a fourth layer 170 of the conductive material applied to a bottom surface of the dielectric material 120 and the bottom surfaces of the pillars 115. The bottom surface of the dielectric material 120 and the bottom surfaces of the pillars 115 are in a plane parallel to and opposite a plane including the conductive pads 155. The fourth layer 170 of the conductive material is applied through an electroless plating process (e.g., an electroless copper plating) in various implementations.

Similarly, a fifth resist layer 175 is applied to the fourth layer 170 of the conductive material in FIG. 18. Hence, the fourth layer 170 of the conductive material is between the bottom surface of the dielectric material 120 and the fifth resist layer 175. The fifth resist layer 175 is thinner than the third resist layer 140 in various implementations. For example, the fifth resist layer 175 has a common thickness as the additional resist layer 130 or the fourth resist layer 165.

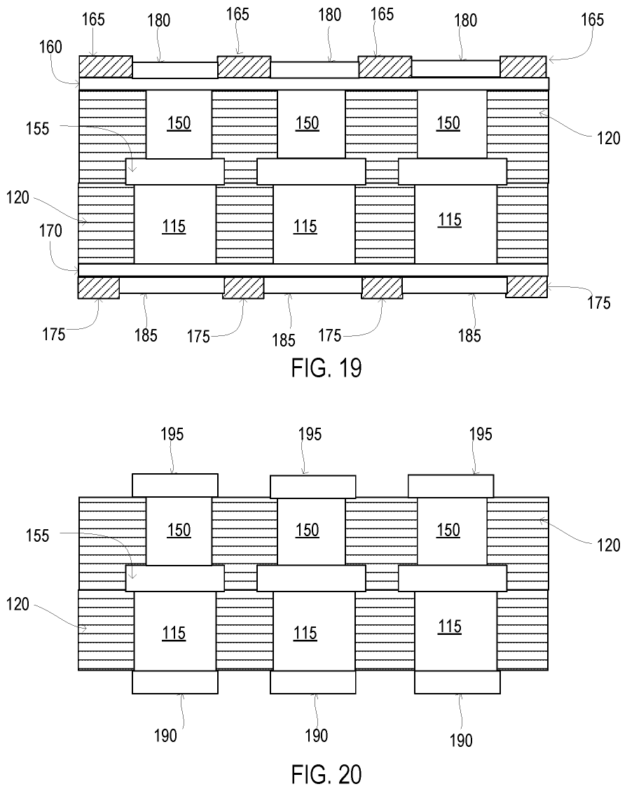

As shown in FIG. 19, portions of the fourth resist layer 165 are removed from portions of the third layer 160 of the conductive material, while portions of the fourth resist layer 165 remain on the third layer 160 of the conductive material, forming a pattern from the removed portions of the fourth resist layer 165 and the remaining portions of the fourth resist layer 165. Similarly, portions of the fifth resist layer 175 are removed from portions of the fourth layer 170 of conductive material, while other portions of the fifth resist layer 175 remain, creating a pattern. For example, photolithography is used to remove one or more portions of the fourth resist layer 165 and one or more portions of the fifth resist layer 175; however, in other implementations different techniques or combinations of techniques are used to remove portions of the additional resist layer 130. In various implementations, a common pattern is used to remove portions of the fourth resist layer 165 and to remove portions of the fifth resist layer 175; however, in other implementations, different patterns are used to remove portions of the fourth resist layer 165 and portions of the fifth resist layer 175.

After removing portions of the fourth resist layer 165, conductive material 180 is applied to the portions of third layer 160 of conductive material exposed from removal of the portions of the fourth resist layer 165, as shown in FIG. 19. In some implementations, the conductive material 180 is applied to the exposed portions of the third layer 160 of conductive material via one or more electroplating processes, while in other implementations the conductive material 180 is applied using other suitable methods. Similarly, conductive material 185 is applied to the portions of the fourth layer 170 of conductive material exposed from removal of the portions of the fifth resist layer 175, as shown in FIG. 19. In various implementations, the conductive material 185 is applied to the exposed portions of the fourth layer 170 of conductive material through one or more electroplating processes.

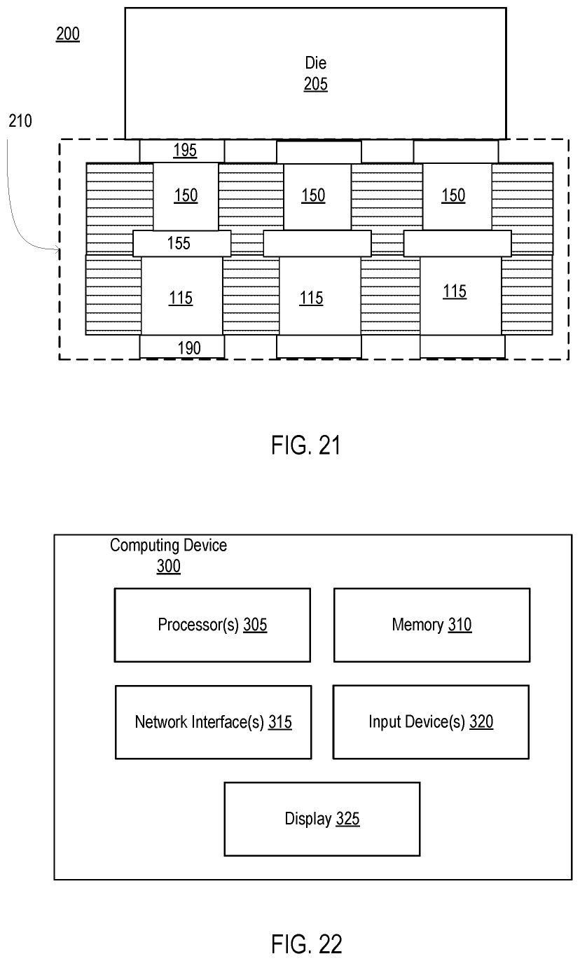

After application of the conductive material 180 to exposed portions of the third layer 160 of conductive material and application of the conductive material 180 to exposed portions of the fourth layer 170 of conductive material, the remaining portions of the fourth resist layer 165 and the remaining portions of the fifth resist layer 175 are removed, as shown in FIG. 20. For example, the remaining portions of the fourth resist layer 165 and the remaining portions of the fifth resist layer 175 are removed using photolithography, while in other examples one or more other methods are used to remove the remaining portions of the fourth resist layer 165 and the remaining portions of the fifth resist layer 175.

Additionally, the third layer 160 of conductive material and the fourth layer 170 of conductive material are removed in FIG. 20. One or more etching processes are used to remove the third layer 160 of conductive material and the fourth layer 170 of conductive material in various implementations. Removing the fourth layer 170 of conductive material results in a second conductive pad 190 coupled to a bottom end of each pillar 115, with adjacent second conductive pads 190 separated by a distance. The conductive material 185 applied to the portions of the fourth layer 170 of conductive material exposed from removing portions of the fifth resist layer 175 in FIG. 19 forms the second conductive pads 190. Similarly, removing the third layer 160 of conductive material results in a third pad 195 coupled to a top end of each additional pillar 150, with adjacent third conductive pads 195 separated by a distance. The conductive material 180 applied to the portions of the third layer 160 of conductive material exposed from removing portions of the fourth resist layer 165 in FIG. 19 forms the third conductive pads 195. The second conductive pads 190 and the third conductive pads 195 are in opposite planes that are parallel to each other. Similarly, the second conductive pads 190 are in a plane that is parallel to a plane including the conductive pads 155, and the third conductive pads 195 are in a plane that is parallel to a plane including the conductive pads 155.

In various implementations, additional layers are applied to a surface of the core shown in FIG. 20 including the second conductive pads 190 or to a surface of the core shown in FIG. 20 including the third conductive pads 195 to form one or more semiconductor components. Hence, the core shown in FIG. 20 is a portion of a substrate, which is a portion of material that mechanically supports coupled components such as a die. In some implementations, the substrate including the core shown in FIG. 20 also electrically couples various components mounted to the substrate via conductive traces, tracks, pads, and the like, with a pillar 115 coupled to an additional pillar 150 providing an electrical connection between a component coupled to the second conductive pad 190 and a component coupled to the third conductive pad 195.

In various implementations, the steps described above in conjunction with FIGS. 12-16 are iteratively repeated to increase a thickness of the core. Repeating the steps described above in conjunction with FIGS. 12-16 result in coupling other pillars to the additional pillars via conductive pads formed as further described above. In different implementations, the steps described above in conjunction with FIGS. 12-16 are iteratively repeated different numbers of times to result in different core thicknesses.

FIG. 21 is a cross-sectional diagram of an example integrated circuit device 200 including a substrate having conductive pillars encapsulated by a dielectric material in accordance with some implementations of the present disclosure. The example integrated circuit device 200 can be implemented in a variety of computing devices, including mobile devices, personal computers, peripheral hardware components, gaming devices, set-top boxes, smart phones and the like (as shown in FIG. 22). The example integrated circuit device 200 of FIG. 21 includes a die 205. The die 205 is a block of semiconducting material such as silicon onto which a functional integrated circuit is fabricated. As an example, the die 205 includes a processor such as a Central Processing Unit (GPU), a Graphics Processing Unit (GPU), or other processor as can be appreciated.

As an example, the die 205 includes a processor 305 of a computing device 300 as shown in FIG. 22. The computing device 300 is implemented, for example, as a desktop computer, a laptop computer, a server, a game console, a smart phone, a tablet, and the like. In addition to one or more processors 305, the computing device 300 includes memory 310. The memory 310 includes Random Access Memory (RAM) or other volatile memory. The memory 310 also includes non-volatile memory such as disk storage, solid state storage, and the like.

In some implementations, the computing device 300 also includes one or more network interfaces 315. In some implementations, the network interfaces 315 include a wired network interface 315 such as Ethernet or another wired network connection as can be appreciated. In some implementations, the network interfaces 315 include wireless network interfaces 315 such as WiFi, BLUETOOTH®, cellular, or other wireless network interfaces 315 as can be appreciated. In some implementations, the computing device 300 includes one or more input devices 320 that accept user input. Example input devices 320 include keyboards, touchpads, touch screen interfaces, and the like. One skilled in the art will appreciate that, in some implementations, the input devices 320 include peripheral devices such as external keyboards, mouses, and the like.

In some implementations, the computing device 300 includes a display 325. In some implementations, the display 325 includes an external display connected via a video or display port. In some implementations, the display 325 is housed within a housing of the computing device 300. For example, the display 325 includes a screen of a tablet, laptop, smartphone, or other mobile device. In implementations where the display 325 includes a touch screen, the display 325 also serves as an input device 320.

The die 205 is coupled to a substrate 210. The substrate 210 is a portion of material that mechanically supports coupled components such as the die 205. In some implementations, the substrate 210 also electrically couples various components mounted to the substrate 210 via conductive traces, tracks, pads, and the like. For example, the substrate 210 electrically couples a component of the die 205 to one or more other components via a pillar 115, an additional pillar 150, a conductive pad 155, and one or more of a second conductive pad 190 and a third conductive pad 195. As further described above in conjunction with FIGS. 1-20, the pillar 115 and the additional pillar 150 have perimeters that are a conductive material, and the conductive pad 155, the second conductive pad 190, and the third conductive pad 195 each comprise the conductive material. Thus, a component of the die 205 electrically contacting the second conductive pad 190 is electrically coupled to another component (of the die 205 or of another component) that electrically contacts the conductive pad 155 or the third conductive pad 195. Thus, in some implementations, the pillar 115, the additional pillar 150, the conductive pad 155, the second conductive pad 190, and the third conductive pad 195 function as a plated through hole electrically coupling a component electrically coupled to the second conductive pad 190 to another component electrically coupled to the third conductive pad 195.

In some implementations, the substrate 210 includes a printed circuit board (PCB), while in other implementations the substrate 210 is another semiconductor device, like die 205 (which may include active components therein). In some implementations, the die 205 is coupled to the substrate 210 via a socket (not shown), where the die 205 is soldered to or otherwise mounted in the socket. In other implementations, the die 205 is directly coupled to the substrate 210 via a direct solder connection or other connection as can be appreciated. In some implementations, the die 205 is coupled to the substrate 210 using a land grid array (LGA), pin grid array (PGA), or other packaging technology as can be appreciated. When the die 205 is coupled to the substrate 210, one or more electrical connections between the die 205 and the second conductive pad 190 (or the third conductive pad 195, depending on how the die 205 is coupled to the substrate) are formed.

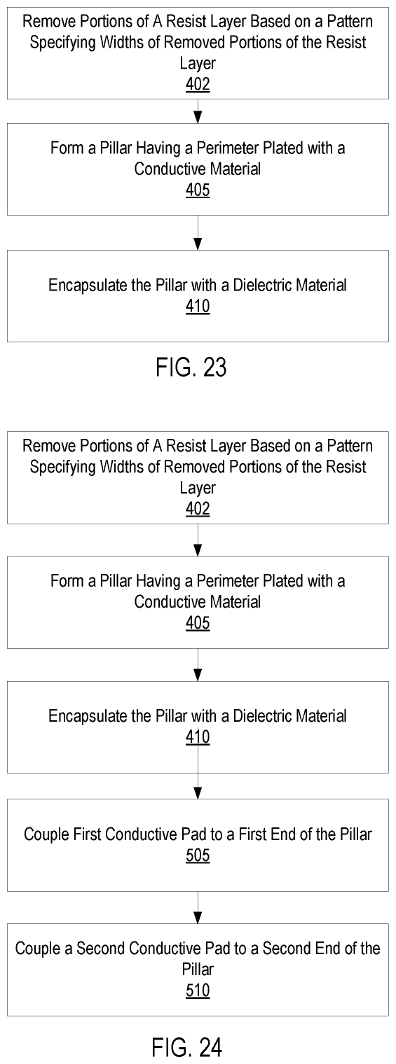

For further explanation, FIG. 23 sets forth a flow chart illustrating an example method for manufacturing an integrated circuit device assembly including a substrate having conductive pillars encapsulated by a dielectric material according to implementations of the present disclosure. The method of FIG. 23 includes removing 402 portions of a resist layer based on a pattern specifying widths of removed portions of the resist layer. In various implementations, the portions of the resist layer are removed 402 using lithography, such as photolithography, as further described above in conjunction with FIGS. 1-4. The method further includes forming 405 a pillar 115 having a perimeter that is plated with a conductive material. As further described above in conjunction with FIGS. 1-4, in various implementations the conductive pillar 115 is formed 405 by applying a resist layer 105 to a layer 100 of conductive material (e.g., copper). Portions of the resist layer 105 are removed 402 through lithography or other suitable methods in various implementations, and the conductive material is applied to locations where the resist layer 105 was removed. For example, an electroplating process is used to apply the conductive material. In some implementations, application of the material to the locations where the resist layer 105 was removed creates a hollow pillar 115 with a perimeter comprising the conductive material. In some implementations, a set of pillars 115 is formed by removing portions of the resist layer 105 based on a pattern that specifies distances between pillars 115. Conductive material is applied to the locations where the portions of the resist layer 105 was removed in various implementations. As further described above in conjunction with FIG. 2, in some implementations the pattern specifies a width less than 400 micron or specifies a width less than 200 microns, allowing the pillars 115 of the set to be separated by a smaller distance than conventional techniques creating holes by drilling into a substrate material.

The method of FIG. 23 also includes encapsulating 410 the pillar 115 with a dielectric material 120. In some implementations, the dielectric material 120 surrounds the pillar 115 by occupying spaces around the pillar 115; hence, encapsulating a pillar 115 with the dielectric material 120. In some implementations, a conversion coating is applied to the pillar 115 before the pillar 115 is encapsulated 410 in the dielectric material 120, with the conversion coating improving improve adhesion of the dielectric material 120 to one or more surfaces of the pillar 115. For example, black oxide is applied to an exterior surface of the conductive material forming the perimeter of the pillar 115, with the dielectric material 120 applied to encapsulate 410 the pillar 115 after application of the black oxide. In various implementations the dielectric material 120 is an organic material. For example, the dielectric material 120 includes resin and glass filler. Further, the dielectric material 120 is a flame redardant-4 (“FR-4”) material in various implementations. The dielectric material 120 is applied using compression molding in some implementations. In other implementations the dielectric material 120 is applied using vacuum lamination, while in further implementations the dielectric material 120 is applied via liquid coating. However, different methods or combinations of methods are used to encapsulate 410 the pillars 115 with the dielectric material 120 in various implementations.

For further explanation, FIG. 24 sets forth a flow chart illustrating an example method for manufacturing an integrated circuit device assembly including a substrate having pillars encapsulated by a dielectric material according to implementations of the present disclosure. The method of FIG. 24 is similar to FIG. 23 in that the method of FIG. 24 includes removing 402 portions of a resist layer based on a pattern specifying widths of removed portions of the resist layer. In various implementations, the portions of the resist layer are removed 402 using lithography, and forming 405 a pillar having a perimeter plated with a conductive material and encapsulating 410 the pillar 115 with dielectric material 120.

The example method shown in FIG. 23 differs from FIG. 22 in that the method of FIG. 23 also includes coupling 505 a first conductive pad 155 to a first end of the pillar 115. The first conductive pad comprises a conductive material and is proximate to a first surface of the dielectric material 120 encapsulating the pillar 115. In various implementations where the pillar 115 is hollow, the first conductive pad 155 is solid and forms a cap over an opening at the first end of the pillar 115. The first conductive pad 155 and the conductive material forming the perimeter of the pillar 115 are a common material in various implementations. FIGS. 7-11 further describing coupling 505 the first conductive pad 155 to the first end of the pillar 115.

Additionally, a second conductive pad 190 is coupled 510 to a second end of the pillar 115, where the second end of the pillar 115 is opposite the first end of the pillar 115. The second conductive pad 190 is proximate to a second surface of the dielectric material 120 that is opposite to the first surface of the dielectric material 120. In various implementations where the pillar 115 is hollow, the second conductive pad 190 is solid and forms a cap over an opening at the second end of the pillar 115. The second conductive pad 190 and the conductive material forming the perimeter of the pillar 115 are a common material in various implementations. FIGS. 18-20 further describe coupling 510 the second conductive pad 190 to the first end of the pillar 115.

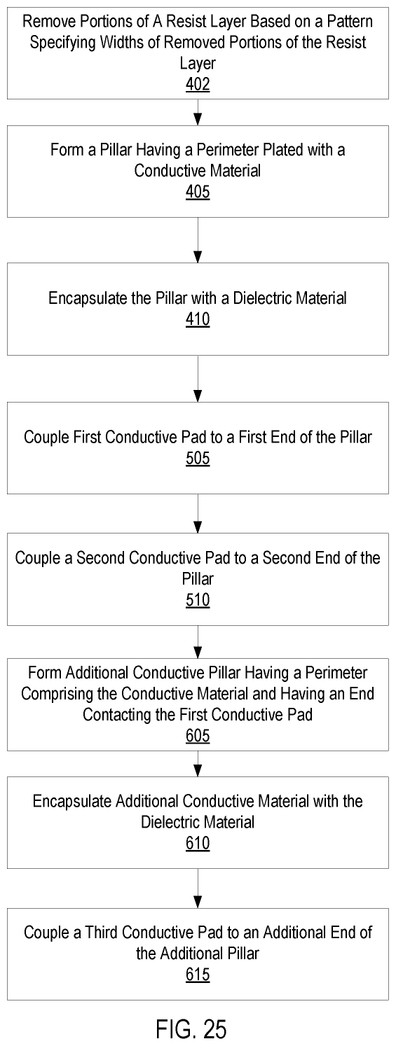

For further explanation, FIG. 25 sets forth a flow chart illustrating an example method for manufacturing an integrated circuit device assembly including a substrate having pillars encapsulated by a dielectric material according to implementations of the present disclosure. The method of FIG. 25 is similar to FIG. 24 in that the method of FIG. 25 includes removing 402 portions of a resist layer based on a pattern specifying widths of removed portions of the resist layer and forming 405 a pillar having a perimeter plated with a conductive material and encapsulating 410 the pillar 115 with dielectric material 120. The method of FIG. 25 also couples 505 a first conductive pad 155 to a first end of the pillar 115 and couples 510 a second conductive pad 190 to a second end of the pillar 115.

The example method shown in FIG. 25 differs from the example method of FIG. 24 by also forming 605 an additional pillar 150 that has a perimeter comprising the conductive material. An end of the additional pillar is contacts the first conductive pad 155. As the additional pillar 150 and the pillar 115 each have perimeters that are the conductive material and the first conductive pad 155 is the conductive material, contact between the additional pillar 150 and the first conductive pad 155 electrically connects the pillar 115 to the additional pillar 150. Formation of the additional pillar 150 is further described above in conjunction with FIGS. 12-15.

The additional pillar 150 is encapsulated 610 with additional dielectric material 120 where a surface of the additional dielectric material 120 is proximate to a surface of the dielectric material 120 proximate to the conductive pad 155. Hence, the additional dielectric material 120 encapsulates the additional pillar 150 as the dielectric material 120 encapsulates the conductive pillar 115.

Additionally, a third conductive pad 195 is coupled 615 to an additional end of the additional pillar 150, where the additional end of the additional pillar 150 is opposite to the end of the additional pillar 150 contacting the first conductive pad 155. The third conductive pad 195 is proximate to an additional surface of the additional dielectric material 120 that is opposite the surface of the additional dielectric material. Coupling the additional end of the additional pillar 150 to the third conductive pad 195 is further described above in conjunction with FIGS. 16-20. The example method described in conjunction with FIG. 25 allows a component electrically contacting the third conductive pad 195 to be electrically coupled to another component that electrically contacts the second conductive pad 190. This allows the pillar 115, the additional pillar 150, the first conductive pad 155, the second conductive pad 190, and the third conductive pad 195 to electrically connect components on opposite sides of the substrate.

In view of the explanations set forth above, readers will recognize that manufacturing an integrated circuit device assembly including a substrate having pillars encapsulated by a dielectric material as described herein allows the conductive pillars to be placed nearer to each other than conventional methods that use holes drilled in a substrate to create holes that are subsequently plated. This reduced spacing between conductive pillars improves power delivery to components of the integrated circuit device assembly and increases signal integrity of communication of data between components coupled to each other on opposite sides of a substrate via the pillars.

It will be understood from the foregoing description that modifications and changes can be made in various implementations of the present disclosure. The descriptions in this specification are for purposes of illustration only and are not to be construed in a limiting sense. The scope of the present disclosure is limited only by the language of the following claims.

What is claimed is:

1. A method for forming a core for a substrate comprising:
removing portions of a resist layer based on a pattern specifying widths of removed portions of the resist layer;
forming a set of pillars by plating remaining portions of the resist layer with a conductive material, so each pillar of the set has a perimeter plated with the conductive material; and
encapsulating each pillar of the set of pillars with a dielectric material.

2. The method of claim 1, wherein the dielectric material comprises an organic material.

3. The method of claim 1, wherein the dielectric material includes low loss resin or glass filler.

4. The method of claim 1, wherein encapsulating each pillar of the set of pillars with the dielectric material comprises:
applying the dielectric material using compression molding.

5. The method of claim 1, wherein encapsulating each pillar of the set of pillars with the dielectric material comprises:
applying the dielectric material using vacuum lamination.

6. The method of claim 5, wherein encapsulating each pillar of the set of pillars with the dielectric material comprises:
applying the dielectric material using liquid coating.

7. The method of claim 1, further comprising:
removing portions of the dielectric material that are higher than a height of the pillars of the set.

8. The method of claim 7, wherein removing portions of the dielectric material that are higher than the height of the pillars of the set comprises:
grinding portions of the dielectric material that are higher than the height of the pillars of the set.

9. The method of claim 1, further comprising:
coupling a first conductive pad to a first end of a pillar, the first conductive pad proximate to a first surface of the dielectric material; and
coupling a second conductive pad to a second end of the pillar, the second end of the pillar opposite the first end of the pillar and the second conductive pad proximate to a second surface of the dielectric material that is opposite the first surface of the dielectric material.

10. The method of claim 9, wherein coupling the first conductive pad to a first end of the pillar comprises:
applying an additional layer of the conductive material to a surface of set of pillars nearest the first surface of the dielectric material; and
removing portions of the additional layer of the conductive material other than the first conductive pad.

11. The method of claim 9, further comprising:
forming an additional pillar by lithographically removing portions of an additional resist layer applied to the additional layer of the conductive material and plating an additional perimeter of a remaining portion of the additional resist layer with the conductive material, a perimeter of the additional pillar comprising the conductive material and an end of the additional pillar contacting the first conductive pad coupled to the first end of the pillar; and
encapsulating the additional pillar with additional dielectric material, where a surface of the additional dielectric material is proximate to the first surface of the dielectric material.

12. The method of claim 11, further comprising:
coupling a third conductive pad to an additional end of the additional pillar, the additional end of the additional pillar opposite the end of the additional pillar and the third conductive pad proximate to an additional surface of the additional dielectric material that is opposite the surface of the additional dielectric material.

13. The method of claim 1, wherein adjacent pillars of the set are separated by a distance between centers of adjacent pillars that does not exceed 400 microns.

14. The method of claim 1, wherein adjacent pillars of the set are separated by a distance between centers of adjacent pillars that does not exceed 200 microns.

15. A semiconductor device comprising:
a pillar having a perimeter plated with a conductive material;
dielectric material encapsulating the pillar;
an additional pillar, a perimeter of the additional pillar comprising the conductive material and an end of the additional pillar contacting a first conductive pad coupled to a first end of the pillar; and
additional dielectric material encapsulating the additional pillar, a surface of the additional dielectric material proximate to a first surface of the dielectric material that is proximate to the first end of the pillar.

16. The semiconductor device of claim 15, wherein the dielectric material comprises an organic material.

17. The semiconductor device of claim 15, wherein the additional dielectric material comprises an organic material.

18. The semiconductor device of claim 15, further comprising:
a second conductive pad coupled to a second end of the pillar, the second end of the pillar opposite the first end of the pillar and the second conductive pad proximate to a second surface of the dielectric material that is opposite the first surface of the dielectric material.

19. The semiconductor device of claim 15, wherein the pillar is included in a set of pillars where adjacent pillars of the set are separated by a distance between centers of adjacent pillars that does not exceed 400 microns.

20. The semiconductor device of claim 15, wherein the pillar is included in a set of pillars where adjacent pillars of the set are separated by a distance between centers of adjacent pillars that does not exceed 200 microns.

21. The semiconductor device of claim 15, wherein the pillar is formed by lithographically removing portions of a resist layer and plating a perimeter of a remaining portion of the resist layer with the conductive material with the conductive material and the additional pillar is formed by lithographically removing portions of an additional resist layer and plating an additional perimeter of a remaining portion of the additional resist layer with the conductive material.
